(19) United States
(12) Patent Application Publication
(10) Pub. No.: US 2006/0114979 A1
(43) Pub. Date: Jun. 1, 2006

(54) Fully parametric equalizer

(76) Inventors: Kim Rishoj Pedersen, Ega (DK); Knud Bank Christensen, Ryomgard (DK)

Correspondence Address: CANTOR COLBURN, LLP, 55 GRIFFIN ROAD SOUTH, BLOOMFIELD, CT, 06002, US

(21) Appl. No.: 10/538,593

(22) PCT Filed: Dec. 9, 2002
(86) PCT No.: PCT/DK02/00831

§ 371 Date: Jun. 9, 2005

(51) Int. Cl. H03H 7/30

(52) U.S. Cl. 375/229

(57) ABSTRACT

The invention relates to a parametric equalizer comprising filtering means (FM), user interface means (UIM), audio signal input means and audio signal output means, said filtering means comprising at least one filter block (FIB) said user interface means (UIM) facilitating adjustment of corner frequency (fc), Shape (Q) and gain (G), said user interface means (UIM) comprising a further adjustment parameter (SYM), said user interface means being mapped by means of coefficient adjustment algorithms (CAD) into filter coefficient settings (FCP) of the at least one filter block (FIB), which when established reflects the adjustment of the user interface means (UIM) said further adjustment parameter (SYM) providing a filter coefficient setting (FCS) comprising a combined adjustment of at least one zero frequency, pole frequency, zero Q and pole Q of at least one filter block.

### FIELD OF THE INVENTION

The present invention relates to a parametric equalizer according to claim 1.

### BACKGROUND OF THE INVENTION

Today's equalizers can be divided into graphical and parametrical equalizers. Both types can be implemented in analog or digital signal processing technology. This invention deals with parametric equalizers in analog as well as digital implementations.

Generally a graphical equalizer benefits of the fact that the complete audio spectrum may be divided into several fixed regions with levels controlled in an intuitive way by a user of the equalizer. A significant problem of the graphical equalizer is, however, that the equalizer is quite inflexible and provides very little possibility of accurate control by a user due to the fact that the user is typically restricted to utilization of the pre-defined bands. In practice, such problem would only be solved by the use of even more than thirty bands. Such a device would typically be a very expensive device simply because of sheer duplication of circuitry. Much of the circuitry will be wasted when dealing with several types of equalizing tasks because such types of tasks typically only involve adjustment of two or three bands while others should be left unaffected by the filtering.

An equalizer with adjustable frequency has therefore been provided for the purpose of optimizing the use of signal processing circuitry. Such an equalizer is referred to as a parametric equalizer and has upon introduction in 1972 found wide use especially in professional or semi-professional contexts.

Basically a parametric equalizer features very few control parameters, which, on the other hand may control the curve response with very high resolution.

Typical control parameters are gain, center frequency and Q. Moreover, some parametric equalizers provide three different filter types, a low shelf filter, a bell-shaped filter and a high shelf filter.

A parametric equalizer can produce a very sharp notch, as a graphic equalizer, and maintain the shape over several decades or bands. A parametric equalizer may, contrary to most applicable graphical equalizers produce a magnitude response boost or attenuation at any frequency and may therefore match the average desired sound filtering characteristic somewhat better than graphic equalizers.

An application of a parametric equalizer may for example be suppression of low frequency microphone noise.

A typical parametrical equalizer may comprise a number of filter blocks, which may be cascaded for the purpose of obtaining one desired combined transfer function of the cascaded filters.

Presently, each block is typically one of three types: Low-shelf, parametric (bell-shaped) and high-shelf filter. The low/high shelf filters have three parameters each: Gain G, corner frequency f and slope (or Q), and the parametric filters have three similar parameters: Gain G, center frequency f_{c} and bandwidth BW (or Q).

A problem of the prior art parametric equalizers is that the freedom of operation is somewhat limited and that the full use of the parametric equalizers for certain common desired filter characteristics requires several cascaded filters, thereby increasing the complexity of the complete system and evidently, increasing the costs involved, due to the fact that several units must be applied for the purpose of obtaining the single desired characteristics.

It is the object of the invention to provide an equalizer featuring the above-mentioned advantages of prior art parametric equalizers while ameliorating the above-mentioned disadvantages of the prior art.

### SUMMARY OF THE INVENTION

The invention relates to a parametric equalizer comprising

filtering means (FM), user interface means (UIM), audio signal input means and audio signal output means,

said filtering means comprising at least one filter block (FIB)

said user interface means (UIM) comprising means for adjustment of parameters: corner frequency (fc), shape (Q) and gain (G),

said parametric equalizer comprising means for establishing a variable magnitude response symmetry of said at least one filter block (FIB).

According to the invention, it should be noted that the adjustment parameter referred to as a non-trivial parameter and mentioned as “gain” above refers to the sign characteristic of the log magnitude response of the applied filter, i.e. whether the filter defines a boost or an attenuation at the corner frequency.

According to the invention, non-trivial degrees of freedom are the degrees of freedom left, when the overall gain is disregarded or simply handled as a product of the overall gains of the individual filter blocks. In other words, the complete number of degrees of freedom, when dealing with for example a biquadratic filter block, is five, that is one trivial degree of freedom being the overall gain of the filter block and four non-trivial degrees of freedom. This understanding of degrees of freedom is further explained in the detailed description.

Elsewhere, the parameter global gain or overall gain refers to a trivial parameter corresponding to the linear volume setting of the applied filter block or group of filter blocks.

According to the invention, the further adjustment parameter, exemplified by the symmetry parameter, facilitates the possibility of adjustment of the symmetry of the filter magnitude response, both by providing conventional obtainable filter types, such as low-shelf, bell-shaped and high shelf and mixtures or intermediates (with respect to gain symmetry) thereof.

Such intermediate filter would according to one embodiment of the invention comprise a continuos interval of curve shape defined by variation of the symmetry parameters according to the invention. According to a preferred embodiment of the invention, the symmetry may be varied between low frequency gain boost/attenuation anti-symmetry via center frequency symmetry (e.g. bell-shaped) to high frequency boost/attenuation anti-symmetry.

According to a preferred embodiment of the invention, a continues interval (may of course be established as a high resolution set of discrete filters in the digital world) of filter shapes having magnitude response symmetry varying from one sign of asymmetry to the opposite sign of asymmetry. Preferably, the available continuous number of filter symmetries should comprise the symmetrical instance of the filter design corresponding to the bell-shape.

It should be noted that the gain, Q and fc preferably may be adjusted at every available setting of the Symmetry parameter.

An example of available equalizer filters according to an embodiment of the invention is a filter featuring adjustable asymmetrical over-/undershoot of the filter magnitude response at the selected corner frequency, gain and Q.

According to the invention, the new adjustment parameter may be referred to as the symmetry parameter. The variable symmetry parameter should not be confused with the shape aspects referring to prior art parametric equalizers' variable Q.

According to the invention, the improved control of the equalizer may in fact surprisingly be obtained “free of charge” due to the fact that the improved control may in fact be obtained by the use of conventional filter types, such as biquadratic filter blocks, only now utilizing all four non-trivial degrees of freedom simultaneously.

As it has been appreciated the filtering structure of a parametric equalizer may be regarded as relatively simple at least in the sense that the huge number of processing blocks of for example a graphic equalizer may be avoided.

According to the present invention, this advantage has been maintained while adding significant adjustment features to the user.

According to a particular user-friendly embodiment of the invention, the adjustment parameter may be practically “dimmed” for the purpose of emulating a conventional parametric equalizer. In this way, a user feeling uncomfortable with the adjustment opportunities provided according to the invention may simply convert the equalizer into a conventional and familiar sound-processing device.

In an embodiment of the invention, the user interface means UIM comprises a further symmetry adjustment parameter SYM for establishing a variable symmetry of the magnitude response of said at least one filter block FIB.

said user interface means is mapped by means of coefficient adjustment algorithms into filter coefficient settings FCS of the at least one filter block FIB, which when established reflects the adjustment of the user interface means UIM

said further adjustment parameter SYM provides a filter coefficient setting FCS comprising a combined adjustment of at least one zero frequency, pole frequency, zero Q and pole Q of the magnitude response at least one filter block.

In an embodiment of the invention said user control means facilitates adjustment of corner frequency, fc, shape,Q, gain and symmetry, SYM.

In an embodiment of the invention said filter coefficient settings FCS comprise digital coefficients.

In an embodiment of the invention said filter coefficient settings FCS comprises analogue values established by means of adjustable analogue filter components of said at least one filtering means.

In an embodiment of the invention said filtering means comprises less than twenty individually adjustable filter blocks FIB, preferably less that ten and most preferably less than six.

It should be noted that the filter blocks of a filtering means, e.g. a parametric equalizer preferably should be individually adjustable, thereby facilitating the cascading and adjusting of some or all the filter blocks of the parametric equalizer.

In an embodiment of the invention at least one of said filtering blocks comprises biquad filters (biquad: biquadratic).

In an embodiment of the invention said parametric equalizer comprises at least one, preferably at least three cascaded biquadratic filters.

In an embodiment of the invention said filtering means is analogously implemented.

In an embodiment of the invention said filtering means is digitally implemented.

In an embodiment of the invention said filtering means comprises gain compensation means adapted for compensation of alteration of the filtering block gain invoked by a changed setting of the further adjustment parameter.

In an embodiment of the invention said filtering means comprises corner frequency compensation means adapted for compensation of alteration of the corner frequency of the filtering block invoked by a changed setting of the further adjustment parameter SYM.

In an embodiment of the invention said further adjustment parameter is adapted for providing an adjustment of both the asymmetry around the corner frequency of at least one filter block FIB and the asymmetry around the half gain of the at least one filter block over at least a part of the frequency range of the filter block.

In an embodiment of the invention said user interface provides at least four different asymmetries of filter setting for at least a part of the frequency range.

In an embodiment of the invention said further adjustment parameter SYM enables the user to gradually transform the filter block FIB between a low-shelf filter characteristic and a high-shelf.

It should be noted that several other desirable asymmetries than the well known low-shelf and high shelf equalizer filters may define the endpoints of the available asymmetries. Even though it is highly preferred that the available symmetries (or rather asymmetries) are defined within an interval of asymmetries in order to facilitate the user to grasp the available modifications, discrete, non-continuous sets of filter characteristics may be offered.

In an embodiment of the invention said further adjustment parameter (SYM) enables the user to gradually transform the filter block (FIB) from a low-shelf into a bell-shape and further into a high-shelf, thus defining at least one more than the three standard filter types.

In an embodiment of the invention the number of said adjustment parameters correspond to the number of degrees of freedom of the at least one filter block.

In an embodiment of the invention the number of said adjustment parameters is four times the number of non-trivial degrees of freedom of at least one biquad filter block.

In an embodiment of the invention the number of non-trivial degrees of freedom of each of a number of cascaded filter blocks is at least four.

A further degree of freedom may be a global gain setting, which may be associated to each filter block or may be shared as a global gain setting shared by all the connectable, typically cascadable, filter blocks.

In an embodiment of the invention the symmetry parameter may be set by means of the user interface to at least four different values, preferably a continues interval of values in the analog or digital embodiment.

In an embodiment of the invention the adjustment parameters are converted into filter coefficient settings (FCS) triggered by the setting of the adjustment parameters by the user.

According to the invention, the filter coefficient settings may be established “on the fly” triggered by the setting of the adjustment parameters by a user. In this way, memory may be saved.

In an embodiment of the invention the conversion of adjustment parameters into filter coefficient settings is invertible.

In an embodiment of the invention the given filter coefficient settings may be converted into corresponding adjustment parameters.

According to the invention, an initially applied filter may be presented to the user in corresponding parametric equalizer parameter settings. Moreover, the filter may then be tuned by the parametric equalizer according to an embodiment of the invention.

In an embodiment of the invention a method of adjusting the filter coefficients of the filter of a parametric equalizer comprises the step of availing user adjustment of all the degrees of freedom of the transfer function or a block of the transfer function of the filter.

In an embodiment of the invention said availing of user adjustment comprises the steps of adjusting four degrees of freedom per filter block.

In an embodiment of the invention adjustment of the filter coefficients is implemented in a parametric equalizer according to any of claims 1-23.

Moreover, the invention relates to a method of adjusting the filter coefficients of the filter of a parametric equalizer comprising the step of availing user adjustment of all the degrees of freedom of the transfer function or a block of the transfer function of the filter.

### THE DRAWINGS

The invention is described in the following with reference to the drawings of non-limiting examples, of which

FIG. 1 illustrates the principle components applied according to an embodiment of the invention,

FIG. 2 illustrates the filter characteristics according to an embodiment of the invention,

FIG. 3a illustrates a frequency compensated embodiment of the invention,

FIG. 3b illustrates a gain compensated embodiment of the invention,

FIG. 4 illustrates a block diagram of analog state-variable filter

FIG. 5 illustrates a circuit diagram of single analog biquad filter according to an embodiment of the invention,

FIGS. 6a and 6b illustrate the principle of the invertability obtained according to an embodiment of the invention, and

FIG. 7 illustrates a cascade of filter block in an embodiment of the invention, and

### DETAILED DESCRIPTION

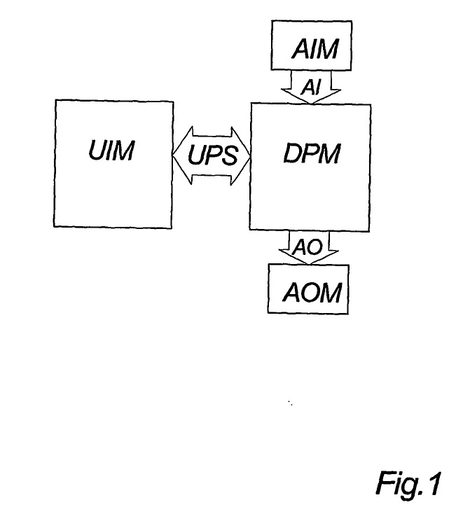

FIG. 1 illustrates the principle components of a parametric equalizer according to an embodiment of the invention.

The main hardware components comprise User Interface Means UIM, Data Processing Means DPM, Audio Input Means AIM and Audio Output Means AOM.

The User Interface Means UIM is adapted for, under the control of a user, establishment of the adjustable parameters controlling the data processing of the Data Processing Means DPM by means of User Parameter Settings UPS controlling the Data Processing Means DPM.

The Data Processing Means DPM comprises suitable data processing hardware and associated circuitry, including memory, clock generators, etc. The Data Processing Means receives Audio Input signals AI provided by the Audio Input Means AIM and outputs Audio Output AO signals to the Audio Output Means AOM.

The Audio Input signals may comprise digital or analog signals. In case of analog signals, the Audio Input Means AIM or the Data Processing Means DPM should preferably comprise the necessary A/D-converters. In case of digital Audio Input AI signals, Audio Input Means AIM or the Data Processing Means DPM should preferably comprise suitable input means.

The User Interface Means UIM comprises suitable adjustments means adapted for manual use. The adjustment means may preferably comprise conventional buttons/kiobs/sliders/etc. and associated display means (not shown) or for example be controlled by a computer implemented interface (not shown) comprising the conventional user input means, such as keyboard and/or mouse and monitor.

Turning now to the theoretical background of the invention.

Classic parametric EQ functions comprise adjustment parameters: Low shelf, parametric and high shelf with varying G,fc and Q

As mentioned above these filters are typically implemented as biquadratic blocks (analog case shown here):

$$H ( s ) = \frac{{b}_{0} {s}^{2} + {b}_{1} s + {b}_{2}}{{a}_{0} {s}^{2} + {a}_{1} s + {a}_{2}} = {g}_{overall} \frac{{s}^{2} + \frac{{ω}_{z}}{{Q}_{z}} s + {ω}_{z}^{2}}{{s}^{2} + \frac{{ω}_{p}}{{Q}_{p}} s + {ω}_{p}^{2}}$$

$$where {g}_{overall} = \frac{{b}_{0}}{{a}_{0}} , {ω}_{z} = \sqrt{\frac{{b}_{2}}{{b}_{0}}} , {Q}_{z} = \frac{\sqrt{{b}_{0} {b}_{2}}}{{b}_{1}} , \\ {ω}_{p} = \sqrt{\frac{{a}_{2}}{{a}_{0}}} , {Q}_{p} = \frac{\sqrt{{a}_{0} {a}_{2}}}{{a}_{1}}$$

It can be seen that H(s) has 5 degrees of freedom: The overall gain of the individual filter block, which is trivial—equivalent to a volume control-, and 4 non-trivial ones, namely the resonance frequencies and Qs of the numerator and denominator respectively. So each of the standard filter types use only 3 out of 4 degrees of freedom, leaving one degree of freedom un-utilized; shelves let Qp=Qz while parametric bell filter let ωp=ωz. To put it another way the 3 standard filter types (low-shelf, parametric and high-shelf) are but samplings along a 4^{th} parameter axis that has so far been hidden from the user.

The Symmetry Parameter

The new parameter will be referred to as the Symmetry parameter, and according to an embodiment of the invention it is defined so that the three traditional filter types correspond to Symmetry=−1, 0 and 1 respectively. A first implementation of the new parameter goes like this (Algorithm 1):

Given user parameters G in dB, ƒ_{c} in Hz, Q and symmetry:

$$g = {10}^{\frac{\vert G \vert}{20}}$$

$$ω = 2 π {f}_{c}$$

$${ω}_{z} = ω \cdot {g}^{- \frac{symmetry}{4}}$$

$${ω}_{p} = \frac{{ω}^{2}}{{ω}_{z}}$$

$${Q}_{z} = Q \cdot {g}^{\vert symmetry \vert - 1}$$

$${g}_{correction} = \{ \begin{matrix} 1 if symmetry \leq 0 \\ {( \frac{{ω}_{p}}{{ω}_{z}} )}^{2} otherwise\end{matrix} \\ H ( s ) = {g}_{correction} \frac{{s}^{2} + \frac{{ω}_{z}}{{Q}_{z}} s + {ω}_{z}^{2}}{{s}^{2} + \frac{{ω}_{p}}{{Q}_{p}} s + {ω}_{p}^{2}} \\ if G < 0 \text{:} H ( s ) = {H ( s )}^{- 1}$$

It should be noted that other definitions or adaptation of the symmetry parameter may be applied according to the invention.

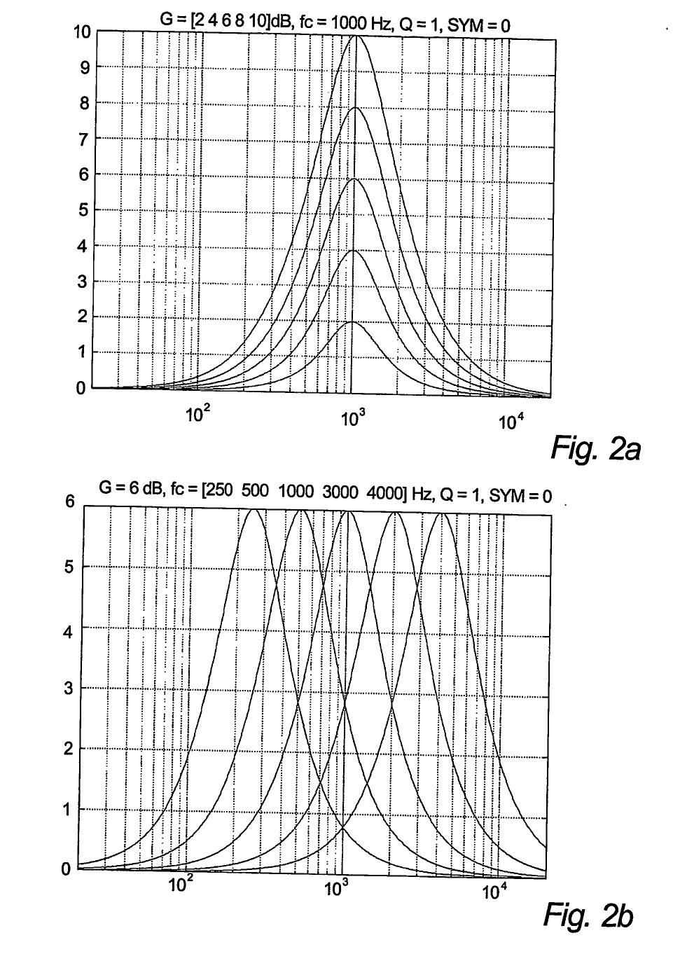

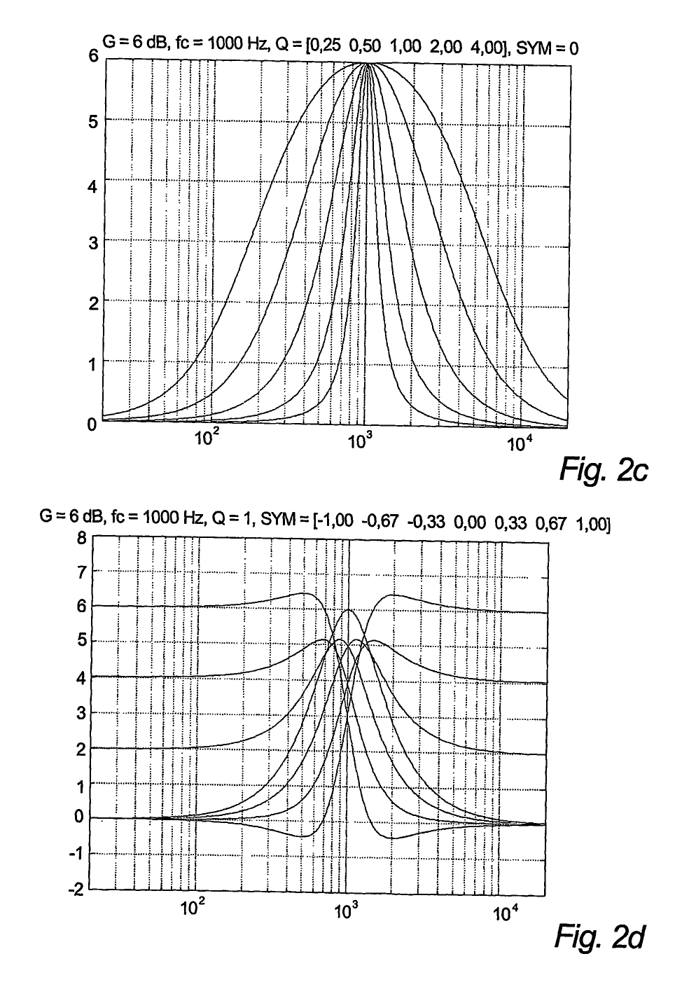

Response examples of a fully parametric EQ, one parameter variation at a time, is illustrated in FIG. 2a-2d.

FIG. 2a illustrates a response of the parametric equalizer with variable gain, fixed fc=1000 Hz, fixed Q=1 and fixed Symmetry=0.

FIG. 2b illustrates a response of the parametric equalizer with fixed gain=6 dB, variable corner frequency fc, fixed Q=1 and fixed Symmetry=0.

FIG. 2c illustrates a response of the parametric equalizer with fixed gain=6 dB, fixed corner frequency fc=1000 Hz, variable Q and fixed Symmetry=0.

FIG. 2d illustrates a response of the parametric equalizer with fixed gain=6 dB, fixed corner frequency fc=1000 Hz, fixed Q=1 and variable Symmetry.

It should be noted that the illustrated obtainable curve forms incorporate both the traditional available settings and the complete range of the fourth parameter, Symmetry.

This is pinpointed in FIG. 2d, where the obtained filter characteristic itself is advantageous and where the filter may be obtained by advantageous and simple control.

In the embodiment of the invention illustrated in FIG. 2d, the SYM (SYM: Symmetry) parameter exhibits two to a certain degree undesired properties:
1. The peak of the magnitude response shifts in frequency causing an un-desirable change of tonal “center of gravity” when operating the Symmetry parameter. This is due to the fact that in algorithm 1, the corner frequency of a shelf filter is defined as mid-slope frequency, while that of a bell shaped is the frequency where the magnitudes deviate the most from 0 dB.
2. At intermediate Symmetry settings, the magnitude may not reach the prescribed gain (G) setting at any frequency. This may not be very intuitive to a user.

Many users will ignore the above-mentioned properties. According to a further embodiment of the invention, these properties will compensated.

The first feature may be reduced by mapping the chosen f_{c} into the pole frequency of all filter symmetries, and thus redefining the meaning of the f_{c} parameter for the classic shelf type filters (Algorithm 2):

Given user parameters G in dB, ƒ_{c} in Hz, Q and symmetry:

$$g = {10}^{\frac{\vert G \vert}{20}}$$

$$ω = 2 π {f}_{c}$$

$${ω}_{z} = ω \cdot {g}^{- \frac{symmetry}{2}}$$

$${Q}_{z} = Q \cdot {g}^{\vert symmetry \vert - 1}$$

$${g}_{correction} = \{ \begin{matrix} 1 if symmetry \leq 0 \\ {( \frac{ω}{{ω}_{z}} )}^{2} otherwise\end{matrix} \\ H ( s ) = {g}_{correction} \frac{{s}^{2} + \frac{{ω}_{z}}{{Q}_{z}} s + {ω}_{z}^{2}}{{s}^{2} + \frac{ω}{Q} s + {ω}^{2}} \\ if G < 0 \text{:} H ( s ) = {H ( s )}^{- 1}$$

The above described mapping may be regarded as a frequency compensation of Symmetry parameter invoked equalizer curve modification, when compared to conventional understanding of the corner frequency.

Evidently, several other more or less intuitive compensations may be applied.

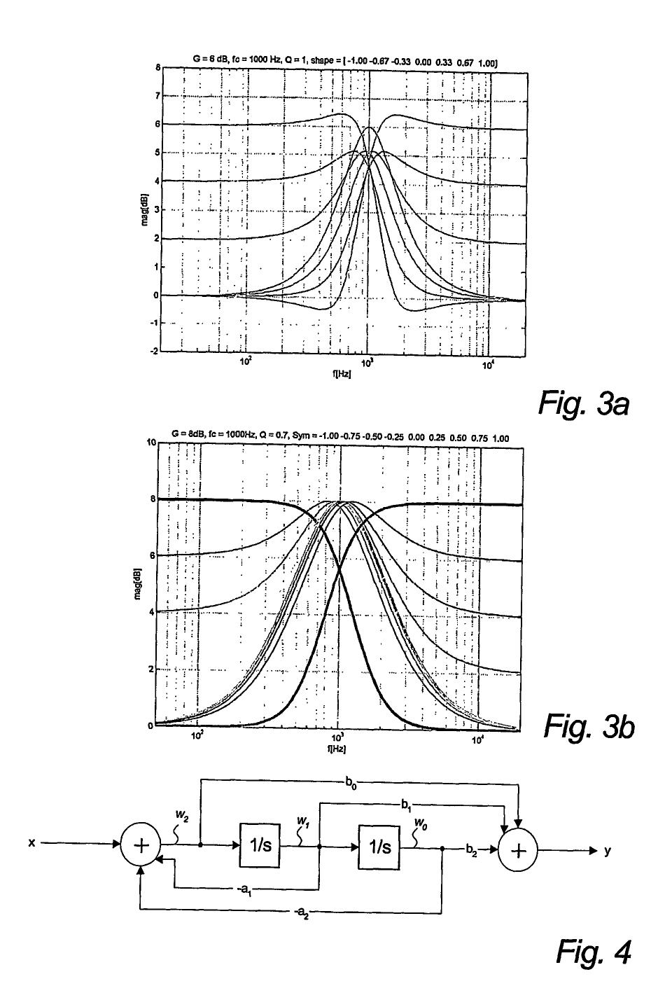

FIG. 3a illustrate the functioning of Symmetry parameter with constant pole frequency as described above.

The second property can be reduced by modifying the Gain parameter, the first order numerator coefficient of H(s) when G>0 or the first order denominator coefficient when G<0 according to some empirical function. Note however, the meaningful relationship between the asymptotic gain and the Symmetry setting in FIGS. 2 and 3:
G_{asymptotic}=|symmetry|·G, both gains in dB

The gain compensation may be obtained according to several different approaches if desired. One approach may be that of fixing the asymptotic values (by gain compensation of the resulting filter) of the gain at low frequencies or at high frequencies.

Another approach would be fixing the gain or attenuation peak at a certain value.

FIG. 3b illustrates a gain compensation applied for the purpose of equaling the maximum gain obtained at or near the corner frequency. It should be stressed, as stated above, that several other manual or automatic compensation techniques may be applied, both with respect to gain and the corner frequency in order to fit the users expectations with respect to the development of the gain and the frequency when modifying the user adjustable parameters. One of several examples of such may for example be a combination of the above described frequency and gain compensation.

Such techniques may also imply empirically established compensations.

Invertibility

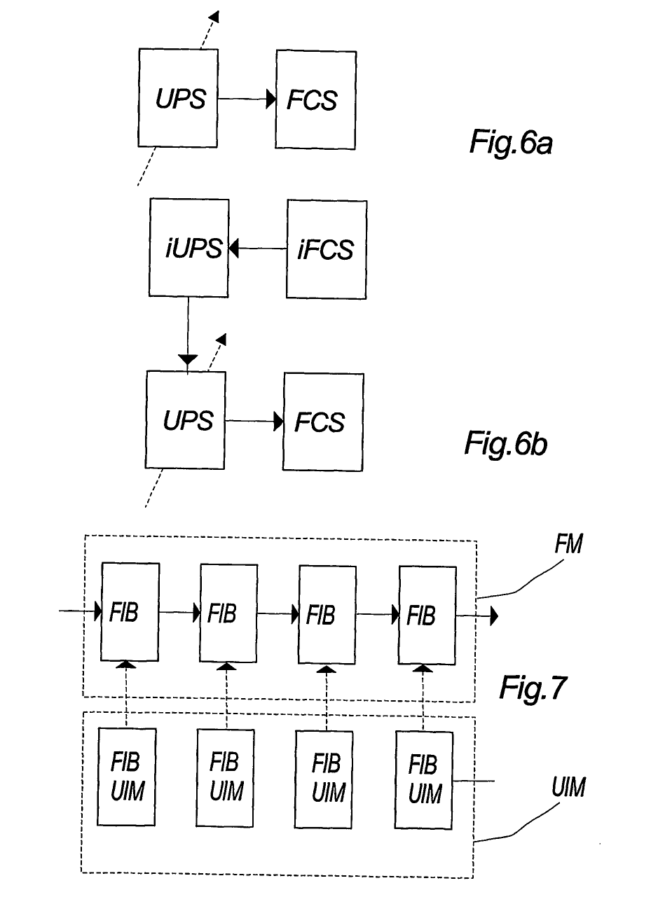

FIG. 6a and FIG. 6b illustrate the possibilities and advantages of the herein referred to invertibility of the parametric equalizer according to an embodiment of the invention. In FIG. 6a, User Parameter Settings UPS may be adjusted by a user. Such settings may, according to an embodiment of the invention comprise gain, corner frequency, Q and Symmetry.

The parameters control suitable hardware means (not shown)

The adjustable settings may then, in a suitable way be transformed into filter coefficient setting FCS, e.g. coefficient of a biquad filter, analog or digital.

In FIG. 6b, however, an initial set of Filter Coefficient Settings iFCS is applied as initial coefficient settings of applied filter. These settings may e.g. be retrieved from a bank of settings available to the user. Such initial settings may for example be established on the basis of complex filter design algorithms or they may represent for example settings of preferred filters, earlier tested and approved by the user.

The settings may then, due to the invertibility of the applied parameters settings and the corresponding filter settings, be converted into corresponding initial User Parameter Settings, iUPS. These settings may then be fine-tuned or modified by the user, by means of his preferred tuning means, the parametric equalizer according to the invention, as illustrated in FIG. 6a.

This invertibilty-feature is in particular an advantage in relation to audio signal processing due to the fact that the input signals, such as voice or instruments, typically varies quite significantly, thereby requiring individual filter settings, not only with respect to variation of sound, but sometimes also with respect for the rendering “room”. Due to the fact that such tuning has to be performed in the parameter domain, it is a significant advantage according to an embodiment of the invention, that filters established on the basis of coefficient settings (e.g. by a filter design program in the coefficient domain) may be presented to the user in the parameter domain.

According to an embodiment of the invention, the user may now retrieve an initial setting completely described by the available adjustable User Parameter Settings UPS and he may modify the parameters by his preferred adjustment means, the parameter modifications available by means of the parametric equalizer.

The principle of releasing the last degree of freedom for user adjustment has provided a parametric equalizer, featuring the same benefits obtained by conventional parametric equalizer with respect to easy and flexible tuning together with the possibility of modifying the obtaining equalizer characteristics into several other curve forms than offered until now.

In principle, the adjustment may be obtained by other types of adjustment parameters than the typical parameters corner frequency, gain and Q.

In practice, an arbitrary order of the applied filter in the parametric equalizer may be converted into a cascade of biquad filters.

As long as the equalizer algorithm is not complicated further than for example algorithm 1 or 2, the parametric equalizer according to an embodiment of the invention is invertible, meaning that there exists a unique translation from filter coefficients back to parameters.

Invertibility may also be expressed as the ability to map a continuum of the coefficient space “back” into parametric equalizer parameter settings.

An inverse algorithm is a little more complicated (Algorithm 3):

$$Given H ( s ) = \frac{{b}_{0} {s}^{2} + {b}_{1} s + {b}_{2}}{{a}_{0} {s}^{2} + {a}_{1} s + {a}_{2}} \\ {ω}_{z} = \sqrt{\frac{{b}_{2}}{{b}_{0}}} ; ω = \sqrt{\frac{{a}_{2}}{{a}_{0}}} \\ {Q}_{z} = {ω}_{z} \frac{{b}_{0}}{{b}_{1}} ; Q = ω \frac{{a}_{0}}{{a}_{1}} \\ symmetry = 0 \\ If ω \neq {ω}_{z} \text{:} symmetry = \frac{2}{2 - \frac{log ( {Q}_{z} ) - log ( Q )}{log ( ω ) - log ( {ω}_{z} )}} Endif *) \\ If symmetry < 0 or \vert symmetry \vert > 1 \text{:} \\ symmetry = \frac{2}{2 - \frac{log ( {Q}_{z} ) - log ( Q )}{log ( ω ) - log ( {ω}_{z} )}} Endif *)$$

$$If \vert symmetry \vert > 0.5 : \\ g = {( \frac{{ω}_{z}}{ω} )}^{- \frac{2}{symmetry}} Else g = {( \frac{{Q}_{z}}{Q} )}^{\frac{1}{\vert symmetry \vert - 1}} Endif$$

$$If \text{‖} symmetry \vert - 1 \vert < {10}^{- 3} \text{:} \\ {M}_{D C} = 20 {log}_{10} ( \frac{{b}_{2}}{{a}_{2}} ) ; {M}_{∞} = 20 {log}_{10} ( \frac{{b}_{0}}{{a}_{0}} ) \\ If ( \vert {M}_{D C} \vert < {10}^{- 3} \& symmetry < 0 ) or ( \vert {M}_{∞} \vert < {10}^{- 3} \& symmetry < 0 ) \text{:} \\ symmetry = - symmetry ; g = \frac{1}{g} \\ Endif \\ Endif \\ If g < 1 \text{:} Q = {Q}_{z} ; {f}_{c} = \frac{{ω}_{z}}{2 π} Else \text{:} {f}_{c} = \frac{ω}{2 π} Endif \\ G = 20 {log}_{10} ( g ) \\ *) \text{:} Here log is a logarithm with any base$$

The invertibility of the fully parametric EQ opens up another line of application besides the normal EQ.

A filter block applied according to the invention provided may, if it is strictly minimum-phase and has equal number of poles and zeros, no matter if it is the result of human adjustment or computer optimization be transformed back into a parameter set that makes sense to human beings, and thus enables the human user to gain understanding of—and add further fine-tuning to—the result of such a computerized filter design. This can be quite useful in advanced development systems e.g. for tuning active loudspeakers.

A strictly minimum phase filter has no zeros in the right-hand half-plane including the jω axis in case of an analogue filter or no zeros on or outside the unit circle in case of a filter.

It may be appreciated that, for the purpose solely of obtaining the possibility of converting a given filter setting into at least one set of corresponding parameters, setting the number of adjustable parameters should at least be the number of the non-trivial degrees of freedom. In other words, NDOFpar≧NDOFcoef, where NDOFpar is the number of adjustable equalizer parameters and NDOFcoef is the number of non-trivial degrees of freedom in the filter transfer function. Most preferably NDOFpar=NDOFcoef.

Analog Implementation

FIG. 4 illustrates the block diagram of an analog implementation of an embodiment of the invention.

A section of the full-parametric EQ can be implemented as an analog state-variable filter, whose block diagram is shown in FIG. 4. The “1/s” blocks are integrators, the “w” nodes are internal signals and the “a” and “b” connections represent connections with gains.

The transfer function of this circuit can be found as follows:

$$\begin{matrix}{w}_{2} = x - \frac{{a}_{1}}{s} {w}_{2} - \frac{{a}_{2}}{{s}^{2}} {w}_{2} ⇔ {w}_{2} [ 1 + \frac{{a}_{1}}{s} + \frac{{a}_{2}}{{s}^{2}} ] \\ = x ⇔ {w}_{2} = \frac{1}{1 + \frac{{a}_{1}}{s} + \frac{{a}_{2}}{{s}^{2}}} x \\ = \frac{{s}^{2}}{{s}^{2} + {a}_{1} s + {a}_{2}} x\end{matrix}$$

$${w}_{1} = \frac{1}{s} {w}_{2} = \frac{s}{{s}^{2} + {a}_{1} s + {a}_{2}} x$$

$${w}_{0} = \frac{1}{s} {w}_{1} = \frac{s}{{s}^{2} + {a}_{1} s + {a}_{2}} x$$

$$\begin{matrix}y = {b}_{2} {w}_{0} + {b}_{1} {w}_{1} + {b}_{0} {w}_{2} \\ = \frac{{b}_{0} {s}^{2} + {b}_{1} s + {b}_{2}}{{s}^{2} + {a}_{1} s + {a}_{2}} x \\ = {b}_{0} \frac{{s}^{2} + \frac{{b}_{1}}{{b}_{0}} s + \frac{{b}_{2}}{{b}_{0}}}{{s}^{2} + {a}_{1} s + {a}_{2}} x\end{matrix}$$

$$H ( s ) = \frac{y}{x} = {b}_{0} \frac{{s}^{2} + \frac{{b}_{1}}{{b}_{0}} s + \frac{{b}_{2}}{{b}_{0}}}{{s}^{2} + {a}_{1} s + {a}_{2}}$$

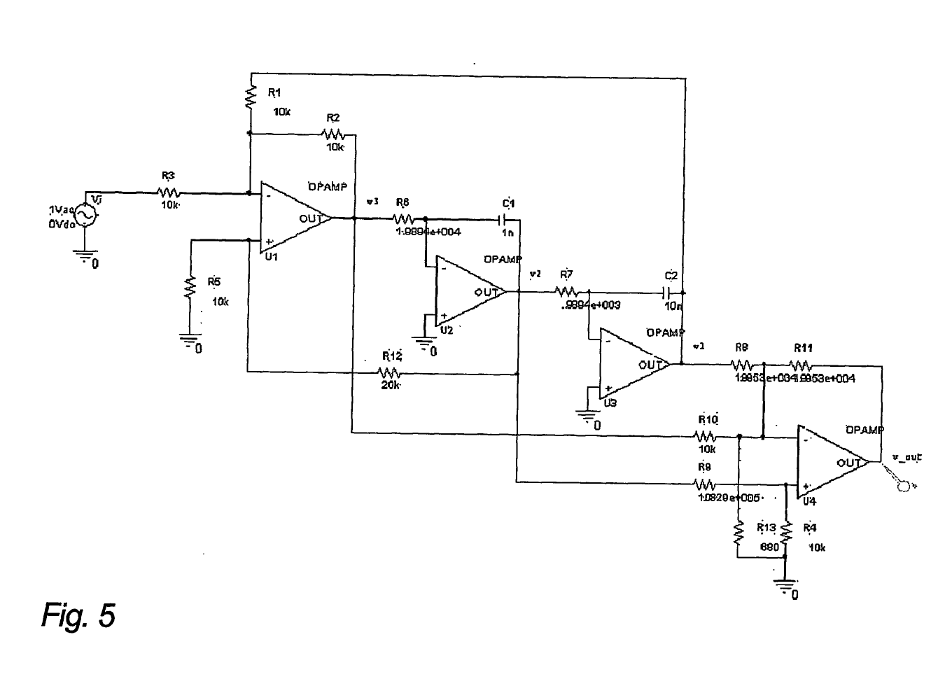

This can be built from real-world electronics using four op-amps in the classical state-variable configuration as illustrated in FIG. 5.

FIG. 5 illustrates the electronic schematics of an analog implementation of the block diagram of FIG. 4. The voltages v₁,v₂,v₃ and vₒᵤₜ can be calculated from vᵢ as follows:

$${v}_{3} = {v}_{2} \frac{{R}_{5}}{{R}_{5} + {R}_{12}} \frac{{R}_{2} + {R}_{1} ∥ {R}_{3}}{{R}_{1} ∥ {R}_{3}} - {v}_{i} \frac{{R}_{2}}{{R}_{3}} - {v}_{1} \frac{{R}_{2}}{{R}_{1}} ;$$

$${v}_{2} = - {v}_{3} \frac{1}{s {R}_{6} {C}_{1}} ; {v}_{1} = - {v}_{2} \frac{1}{s {R}_{7} {C}_{2}} = {v}_{3} \frac{1}{{s}^{2} {R}_{6} {C}_{1} {R}_{7} {C}_{2}} \\ ⇔ {v}_{3} = - {v}_{3} \frac{1}{s {R}_{6} {C}_{1}} \frac{{R}_{5}}{{R}_{5} + {R}_{12}} \frac{{R}_{2} + \frac{{R}_{1} {R}_{3}}{{R}_{1} + {R}_{3}}}{\frac{{R}_{1} {R}_{3}}{{R}_{1} + {R}_{3}}} - {v}_{i} \frac{{R}_{2}}{{R}_{3}} - {v}_{3} \frac{1}{{s}^{2} {R}_{6} {C}_{1} {R}_{7} {C}_{2}} \frac{{R}_{2}}{{R}_{1}} ; do \\ ⇔ {v}_{3} ( \frac{1}{s {R}_{6} {C}_{1}} \frac{{R}_{5}}{{R}_{5} + {R}_{12}} \frac{{R}_{1} {R}_{2} + {R}_{2} {R}_{3} + {R}_{1} {R}_{3}}{{R}_{1} {R}_{3}} + \frac{1}{{s}^{2} {R}_{6} {C}_{1} {R}_{7} {C}_{2}} \frac{{R}_{2}}{{R}_{1}} + 1 ) = - {v}_{i} \frac{{R}_{2}}{{R}_{3}} ; do$$

where the “||” operator is defined as

$$x ∥ y = ( \frac{x \cdot y}{x + y} )$$

or equivalently

$${x}_{1} ∥ {x}_{2} ∥ … ∥ {x}_{n} = {( {\sum }_{i = 1}^{n} {x}_{i}^{- 1} )}^{- 1}$$

Common denominator: s²R₆C₁(R₅+R₁₂)R₁R₃R₇C₂

$$⇔ {v}_{3} ( \frac{s {R}_{7} {C}_{2} {R}_{5} ( {R}_{1} {R}_{2} + {R}_{2} {R}_{3} + {R}_{1} {R}_{3} ) + ( {R}_{5} + {R}_{12} ) {R}_{3} {R}_{2} + {s}^{2} {R}_{6} {C}_{1} ( {R}_{5} + {R}_{12} ) {R}_{1} {R}_{3} {R}_{7} {C}_{2}}{{s}^{2} {R}_{6} {C}_{1} ( {R}_{5} + {R}_{12} ) {R}_{1} {R}_{3} {R}_{7} {C}_{2}} ) = - {v}_{l} \frac{{R}_{2}}{{R}_{3}} ; do$$

$$\begin{matrix}⇔ \frac{{v}_{3}}{{v}_{i}} = - \frac{{R}_{2}}{{R}_{3}} \frac{{s}^{2} {R}_{6} {C}_{1} ( {R}_{5} + {R}_{12} ) {R}_{1} {R}_{3} {R}_{7} {C}_{2}}{{s}^{2} {R}_{6} {C}_{1} ( {R}_{5} + {R}_{12} ) {R}_{1} {R}_{3} {R}_{7} {C}_{2} + s {R}_{7} {C}_{2} {R}_{5} ( {R}_{1} {R}_{2} + {R}_{2} {R}_{3} + {R}_{1} {R}_{3} ) + ( {R}_{5} + {R}_{12} ) {R}_{3} {R}_{2}} \\ = - \frac{{R}_{2}}{{R}_{3}} \frac{{s}^{2}}{{s}^{2} + s \frac{{R}_{7} {C}_{2} {R}_{5} ( {R}_{1} {R}_{2} + {R}_{2} {R}_{3} + {R}_{1} {R}_{3} )}{{R}_{6} {C}_{1} ( {R}_{5} + {R}_{12} ) {R}_{1} {R}_{3} {R}_{7} {C}_{2}} + \frac{( {R}_{5} + {R}_{12} ) {R}_{3} {R}_{2}}{{R}_{6} {C}_{1} ( {R}_{5} + {R}_{12} ) {R}_{1} {R}_{3} {R}_{7} {C}_{2}}} \\ = - \frac{{R}_{2}}{{R}_{3}} \frac{{s}^{2}}{{s}^{2} + s \frac{{R}_{5} ( {R}_{1} {R}_{2} + {R}_{2} {R}_{3} + {R}_{1} {R}_{3} )}{{R}_{6} {C}_{1} ( {R}_{5} + {R}_{12} ) {R}_{1} {R}_{3}} + \frac{{R}_{2}}{{R}_{6} {C}_{1} {R}_{1} {R}_{7} {C}_{2}}} ;\end{matrix}$$

$${v}_{2} = - {v}_{3} \frac{1}{s {R}_{6} {C}_{1}} ; {v}_{1} = {v}_{3} \frac{1}{{s}^{2} {R}_{6} {C}_{1} {R}_{7} {C}_{2}}$$

This leaves us with far more than the necessary 2 degrees of freedom for composing the denominator polynomial:

$$\begin{matrix}Den ( s ) = {s}^{2} + s \frac{{R}_{5} ( {R}_{1} {R}_{2} + {R}_{2} {R}_{3} + {R}_{1} {R}_{3} )}{{R}_{6} {C}_{1} ( {R}_{5} + {R}_{12} ) {R}_{1} {R}_{3}} + \frac{{R}_{2}}{{R}_{6} {C}_{1} {R}_{1} {R}_{7} {C}_{2}} \\ = {s}^{2} + \frac{ω}{Q} s + {ω}^{2}\end{matrix}$$

To simplify things we choose R₁=R₂=R₃=R₅≡R₁₂₃₅ and R₁₂≡2R₁₂₃₅, so

$$Den ( s ) = {s}^{2} + s \frac{1}{{R}_{6} {C}_{1}} + \frac{1}{{R}_{6} {C}_{1} {R}_{7} {C}_{2}}$$

and (continuing calculations)

$$\frac{{v}_{3}}{{v}_{i}} = - \frac{{s}^{2}}{{s}^{2} + s \frac{1}{{R}_{6} {C}_{1}} + \frac{1}{{R}_{6} {C}_{1} {R}_{7} {C}_{2}}} ; {v}_{2} = - {v}_{3} \frac{1}{s {R}_{6} {C}_{1}} ;$$

$${v}_{1} = {v}_{3} \frac{1}{{s}^{2} {R}_{6} {C}_{1} {R}_{7} {C}_{2}} ⇒ \frac{{v}_{2}}{{v}_{i}} = \frac{s \frac{1}{{R}_{6} {C}_{1}}}{{s}^{2} + s \frac{1}{{R}_{6} {C}_{1}} + \frac{1}{{R}_{6} {C}_{1} {R}_{7} {C}_{2}}} ;$$

$$\frac{{v}_{1}}{{v}_{i}} = - \frac{\frac{1}{{R}_{6} {C}_{1} {R}_{7} {C}_{2}}}{{s}^{2} + s \frac{1}{{R}_{6} {C}_{1}} + \frac{1}{{R}_{6} {C}_{1} {R}_{7} {C}_{2}}}$$

So the 3 signals v1, v2 and v3 are LP, BP and HP filtered versions of the input with pass band gains of −1,1 and −1 respectively. Note that these transfer functions are independent of the chosen R₁₂₃₅, which may be chosen arbitrarily to R₁₂₃₅=10 kΩ, for instance. The components determining the pole positions can be chosen as follows:

$${Z}_{typ} = 10 k Ω$$

$${C}_{1} = round\_to \_nearest ( \frac{Q}{ω {Z}_{typ}} )$$

$$\frac{ω}{Q} = \frac{1}{{R}_{6} {C}_{1}} ⇔ {R}_{6} = \frac{Q}{ω {C}_{1}}$$

$${C}_{2} = round\_to \_nearest ( \frac{1}{{Z}_{typ}^{2} {C}_{1} {ω}^{2}} )$$

$${ω}^{2} = \frac{1}{{R}_{6} {C}_{1} {R}_{7} {C}_{2}} ⇔ {R}_{7} = \frac{1}{{ω}^{2} {R}_{6} {C}_{1} {C}_{2}}$$

Now combining the 3 signals in the summing amplifier (U4 in FIG. 5), creates the numerator of the EQ's transfer function:

$$\begin{matrix}{v}_{out} = - \frac{{R}_{11}}{{R}_{10}} {v}_{3} + \frac{{R}_{4}}{{R}_{4} + {R}_{9}} \frac{{R}_{11} + {R}_{8} ∥ {R}_{10} ∥ {R}_{13}}{{R}_{8} ∥ {R}_{10} ∥ {R}_{13}} {v}_{2} - \frac{{R}_{11}}{{R}_{8}} {v}_{1} \\ = \frac{\frac{{R}_{11}}{{R}_{10}} {s}^{2} + \frac{{R}_{4}}{{R}_{4} + {R}_{9}} \frac{{R}_{11} + {R}_{8} ∥ {R}_{10} ∥ {R}_{13}}{{R}_{8} ∥ {R}_{10} ∥ {R}_{13}} \frac{1}{{R}_{6} {C}_{1}} s + \frac{{R}_{11}}{{R}_{8}} \frac{1}{{R}_{6} {C}_{1} {R}_{7} {C}_{2}}}{{s}^{2} + s \frac{1}{{R}_{6} {C}_{1}} + \frac{1}{{R}_{6} {C}_{1} {R}_{7} {C}_{2}}} {v}_{i} \\ = \frac{\frac{{R}_{11}}{{R}_{10}} {s}^{2} + \frac{{R}_{4}}{{R}_{4} + {R}_{9}} \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{10} {R}_{13}} \frac{1}{{R}_{6} {C}_{1}} s + \frac{{R}_{11}}{{R}_{8}} \frac{1}{{R}_{6} {C}_{1} {R}_{7} {C}_{2}}}{{s}^{2} + s \frac{1}{{R}_{6} {C}_{1}} + \frac{1}{{R}_{6} {C}_{1} {R}_{7} {C}_{2}}} {v}_{i} \\ = \frac{{R}_{11}}{{R}_{10}} \frac{{s}^{2} + \frac{{R}_{4}}{{R}_{4} + {R}_{9}} \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} \frac{1}{{R}_{6} {C}_{1}} s + \frac{{R}_{10}}{{R}_{8}} \frac{1}{{R}_{6} {C}_{1} {R}_{7} {C}_{2}}}{{s}^{2} + s \frac{1}{{R}_{6} {C}_{1}} + \frac{1}{{R}_{6} {C}_{1} {R}_{7} {C}_{2}}} {v}_{i}\end{matrix}$$

Again, there are too many degrees of freedoms to obtain the desired overall EQ transfer function:

$$\begin{matrix}EQ ( s ) = \frac{{v}_{out}}{{v}_{i}} \\ = \frac{{R}_{11}}{{R}_{10}} \frac{{s}^{2} + \frac{{R}_{4}}{{R}_{4} + {R}_{9}} \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} \frac{1}{{R}_{6} {C}_{1}} s + \frac{{R}_{10}}{{R}_{8}} \frac{1}{{R}_{6} {C}_{1} {R}_{7} {C}_{2}}}{{s}^{2} + s \frac{1}{{R}_{6} {C}_{1}} + \frac{1}{{R}_{6} {C}_{1} {R}_{7} {C}_{2}}} \\ = {g}_{correction} \frac{{s}^{2} + \frac{{ω}_{z}}{{Q}_{z}} s + {ω}_{z}^{2}}{{s}^{2} + \frac{ω}{Q} s + {ω}^{2}}\end{matrix}$$

Selecting R₁₀ and R₄ to suitable values (e.g. 10 kΩ) the remaining component values are given by:

$$\frac{{R}_{11}}{{R}_{10}} = {g}_{correction} ⇔ {R}_{11} = {g}_{correction} {R}_{10}$$

$$\frac{{R}_{10}}{{R}_{8}} = \frac{{ω}_{z}^{2}}{{ω}^{2}} ⇔ {R}_{8} = {R}_{10} \frac{{ω}^{2}}{{ω}_{z}^{2}}$$

$$\frac{{R}_{4}}{{R}_{4} + {R}_{9}} \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} = \frac{{ω}_{z}}{\frac{{Q}_{z}}{\frac{ω}{Q}}} = \frac{{ω}_{z} Q}{ω {Q}_{z}} \\ ⇔ {R}_{4} \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} = \frac{{ω}_{z} Q}{ω {Q}_{z}} ( {R}_{4} + {R}_{9} ) \\ ⇔ \frac{{ω}_{z} Q}{ω {Q}_{z}} {R}_{9} = {R}_{4} ( \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} - \frac{{ω}_{z} Q}{ω {Q}_{z}} )$$

$$\begin{matrix}⇔ {R}_{9} = \frac{\frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} - \frac{{ω}_{z} Q}{ω {Q}_{z}}}{\frac{{ω}_{z} Q}{ω {Q}_{z}}} {R}_{4} \\ = ( \frac{{R}_{8} {R}_{10} {R}_{11} + {R}_{8} {R}_{11} {R}_{13} + {R}_{10} {R}_{11} {R}_{13} + {R}_{8} {R}_{10} {R}_{13}}{{R}_{8} {R}_{11} {R}_{13}} \frac{ω {Q}_{z}}{{ω }_{z} Q} - 1 ) {R}_{4}\end{matrix}$$

Note that R₉ may become negative. To prevent this from happening within a selected parameter range, we can select a suitably low R₁₃ to boost the amplification of the summing amplifier's non-inverting input.

Digital Implementations

When attempting to make a digital signal processing system work like an analog prototype, like our equalizer, a number of compromises must be made. The discrete-time nature of the digital system causes the frequency representation of digital signals to be limited to the range from 0 Hz to the Nyquist frequency f_{Nq} (half the samplingrate fₛ), while in the continuous analog world, the frequency axis continues towards infinity. The mapping of the infinite analog frequency axis onto the finite digital frequency axis can be done in several, imperfect ways.

Direct Implementation by Bilinear Transform

A computationally convenient method with some virtue is the Bilinear Transform, which maps the entire analog frequency axis (actually the imaginary axis in the complex s-plane) onto the digital frequency axis (actually the unit circle in the complex z-plane), and ensures that stable analog systems are mapped into stable digital systems. The mapping of an infinitely long axis onto a circle of finite circumference is bound to involve some sort of compression or warping. To ensure that the corner frequency of the digital equalizer ends up at the desired value in spite of the warping, it must be pre-warped before doing the design. Unfortunately this only ensures that this one frequency is mapped correctly, the others are still warped, causing a distorted frequency response at high frequencies near f_{Nq}.

The design of a digital version of the parametric equalizer by bilinear transform requires these steps:
1. Prewarp the desired center frequency f_{c} of the resulting digital filter into an analog design center frequency

$${f}_{c , o} = \frac{{f}_{s}}{π} tan ( \frac{π}{{f}_{s}} {f}_{c} )$$
2. Design the analog EQ (EQ: Equalizer) by the earlier described Algorithm 2
3. Apply the bilinear transform by substituting the complex frequency variable s in the analog EQ transfer function by

$$s = 2 {f}_{s} \frac{1 - {z}^{- 1}}{1 + {z}^{- 1}}$$
4. Renormalize the digital transfer function t to

$$H ( z ) = \frac{{b}_{1} + {b}_{2} {z}^{- 1} + {b}_{3} {z}^{- 2}}{1 + {a}_{2} {z}^{- 1} + {a}_{3} {z}^{- 2}}$$

Because the bilinear transform is invertible, the invertibility property holds for the digital implementations of the fully parametric equalizer, when the direct implementation by bilinear transform is used.

Implementation by Digital Design

Do we really need to “design” our digital EQ by some transformation of the analog filter coefficients? Why not use mathematics to approximate the magnitude response of the digital filter directly to that of the analog prototype, or to any other target response for that matter? In simplified terms, this method goes as follows:
1. Convert user parameter settings (G,fc,Q,Symmetry) into analog coefficients described above.
2. Calculate samples of the analog filter's magnitude response at an appropriate selection of frequencies
3. Design a bi-quadratic digital filter to fit the sampled magnitude/frequency points, using general purpose IIR filter design techniques

The digital design method is much preferable if it can be implemented with sufficient computational efficiency on a product platform. Note that it even supports f_{c} settings above the Nyquist frequency.

Since the Implementation by a digital design method in general involves approximate IIR filter design techniques such as least-squares approximation, it may not be invertible, but an inverse approximation may be found, yielding only approximate invertibility. Therefore the Direct Implementation by Bilinear Transform may be the preferable method in cases where exact invertibility is important.

FIG. 7 illustrates a principle design of the filtering means FM of an embodiment of the invention.

The illustrated filtering means FM of a parametric equalizer according to an embodiment of the invention comprises a number of filter blocks FIB, here four.

The filter blocks FIB may be cascaded to form one resulting filtering means.

The individual filtering blocks FIB may according to a preferred embodiment of the invention preferably each comprise a biquad filter

Each of the illustrated filtering blocks FIB is moreover individually controlled by a filtering block user interface means FIBUIM. In other words, each of the illustrated filter blocks may be controlled by a user in the parameter domain by means of for example the parameters corner frequency (fc), Shape (Q), gain (G) and symmetry (SYM). Again, in this context Gain is expressed conventionally as boost/attenuation characteristic while the overall gain is referred to as the general volume setting of the individual filter block. The overall gain may typically be shared between all cascaded filters as a common volume setting.

On other words, a control parameter other than the above described four may be the global or overall gain, which may be applied to the individual filters or more likely as one shared trivial volume control.

It should of course be noted that the number of filtering blocks of a device according to the invention in principle may vary from one to for example hundreds.

Typically, a relatively low number of filter blocks FIB which may be cascaded is preferred, e.g. 3 to 8.

The resulting and/or the individual filter curve settings may be illustrated on one or more displays.

It should moreover be noted that the applied filter blocks comprise biquad filters. However, other filter types of smaller or larger order may be applied if suitable.

1. Parametric equalizer comprising
filtering means (FM), user interface means (UIM), audio signal input means and audio signal output means,
said filtering means comprising at least one filter block (FIB)
said user interface means (UIM) comprising means for adjustment of parameters: corner frequency (fc), shape (Q) and gain (G),
said parametric equalizer comprising further means for adjusting a symmetry parameter independent to the other user parameters, which may be continuously varied in order to provide a smooth transition between low-shelf, bell-shaped and high-shelf filter characteristic of said at least one filter block (FIB).

2. Parametric equalizer according to claim 1, wherein
said user interface means (UIM) comprises a further symmetry adjustment parameter (SYM) for establishing a variable symmetry of the magnitude response of said at least one filter block (FIB),
said user interface means is mapped by means of coefficient adjustment algorithms into filter coefficient settings (FCS) of the at least one filter block (FIB), which when established reflects the adjustment of the user interface means (UIM)
said further adjustment parameter (SYM) provides a filter coefficient setting (FCS) comprising a combined adjustment of at least one zero frequency, pole frequency, zero Q and pole Q of the magnitude response of said at least one filter block.

3. Parametric equalizer according to claim 1, wherein said user interface means facilitates adjustment of corner frequency (fc), Shape (Q), gain and symmetry.

4. Parametric equalizer according to claim 2, wherein
said filter coefficient settings (FCS) comprise digital coefficients.

5. Parametric equalizer according to claim 2, wherein
said filter coefficient settings (FCS) comprise analogue values established by means of adjustable or selectable filter components of said at least one filtering means.

6. Parametric equalizer according to claim 1, wherein
said filtering means comprises less than twenty individually adjustable filter blocks (FIB).

7. Parametric equalizer according to claim 1, wherein
at least one of said filtering blocks comprise a biquatic filter.

8. Parametric equalizer according to claim 1, wherein
said parametric equalizer comprises at least one, cascaded biquadratic filters blocks (FIB) .

9. Parametric equalizer according to claim 1, wherein
said filtering means is analogously implemented.

10. Parametric equalizer according to claim 1, wherein
said filtering means is digitally implemented.

11. Parametric equalizer according to claim 2, wherein
said filtering means comprises gain compensation means adapted for compensation of alteration of the filtering block gain invoked by a changed setting of the further adjustment parameter.

12. Parametric equalizer according to claim 2, wherein
said filtering means comprises corner frequency compensation means adapted for compensation of alteration of the corner frequency of the filtering block invoked by a changed setting of the further adjustment parameter.

13. Parametric equalizer according to claim 2, wherein
said user interface provides at least four different asymmetries of filter setting at least in part of the frequency range.

14. Parametric equalizer according to claim 2, wherein
said further adjustment parameter (SYM) enables the user to gradually transform the filter block (FIB) between a low-shelf and a high-shelf filter characteristic.

15. Parametric equalizer according to claim 2, wherein
said further adjustment parameter (SYM) enables the user to gradually transform the filter block (FIB) from a low-shelf into a bell-shape and further into a high-shelf, thus defining at least one more than said three standard filter types.

16. Parametric equalizer according to claim 1, wherein a number of said adjustment parameters corresponds to a number of non-trivial degrees of freedom of the at least one filter block (FIB).

17. Parametric equalizer according to claims 7, wherein a number of said adjustment parameters is at least a number of non-trivial degrees of freedom of the at least biquad filter block (FIB) times the number of filter blocks (FIB) of said filtering means.

18. Parametric equalizer according to claim 8, wherein a number of non-trivial degrees of freedom of each of a number of said cascaded filter blocks is at least four.

19. Parametric equalizer according to claim 2, wherein the symmetry parameter may be set by means of the user interface to at least four different values.

20. Parametric equalizer according to claim 1, wherein the adjustment parameters are converted into filter coefficient settings (FCS) triggered by setting of the adjustment parameters by the user.

21. Parametric equalizer according to claim 20, wherein the conversion of adjustment parameters into filter coefficient settings is invertible.

22. Parametric equalizer according to claim 1, wherein NDOFpar≧NDOFcoef, where NDOFpar is the number of adjustable equalizer parameters and NDOFcoef is the number of non-trivial degrees of freedom (fc, G, Q, Sym).

23. Parametric equalizer according to claim 1, wherein given filter coefficient settings may be converted into corresponding adjustment parameters.

24-26. (canceled)
